(19) United States
(12) Patent Application Publication
(10) Pub. No.: US 2024/0194557 A1
(43) Pub. Date: Jun. 13, 2024

(54) SYSTEM FOR SURVIVABILITY OF MICROELECTRONICS IN EXTREME TEMPERATURE OPERATING ENVIRONMENTS

(71) Applicant: Lockheed Martin Corporation, Bethesda, MD (US)

(72) Inventors: Keith William Lynn, Charlestown, MA (US); John James Callahan, Wilmington, MA (US); Darren K Brock, Woburn, MA (US); Brent M. Segal, Pembroke, MA (US); Jonathan A. Nichols, North Andover, MA (US); James M. Spatcher, North Kingstown, RI (US); Matthew G. Beckford, Windham, NH (US); Tushar K. Shah, Fulton, MA (US)

(21) Appl. No.: 18/533,848

(22) Filed: Dec. 8, 2023

Related U.S. Application Data
(60) Provisional application No. 63/431,386, filed on Dec. 9, 2022.

(51) Int. Cl. H01L 23/36; H01L 23/00; H01L 29/778

(52) U.S. Cl. CPC H01L 23/36; H01L 24/16; H01L 24/32; H01L 24/73; H01L 29/7786; H01L 2224/16225; H01L 2224/32245; H01L 2224/73253

(57) ABSTRACT

A system and method for operating and fabricating microelectronics for use in extreme-temperature operating environments is disclosed. The microelectronics are designed for operating at conditions that may include temperatures greater than three hundred degrees Celsius. The system and method include one or more modules that each comprise a substrate, a package lid, and an integrated circuit die. A package lid that encloses the integrated circuit die and is disposed on the opposite side of the integrated circuit die from that of a substrate. A thermo-mechanical attachment layer is provided between the integrated circuit die and package lid. Additionally, one or more microfabricated metal pillars that incorporate both thermo-mechanical pathways and signal pathways are provided to connect the integrated circuit die to the substrate.

### TECHNICAL FIELD

This disclosure generally relates to a system and method for the survivability of microelectronics in extreme-temperature operating environments.

### BACKGROUND

There exist multiple applications that require the operation of microelectronics in thermal environments exceeding commercial tolerances of 300° C. In some circumstances, the ability to control the thermal environments via heat removal or insulation is not an option due to a lack of thermal gradient with surrounding environments or geometric constraints of the system operations. Examples of controlling the thermal environments include sensor configurations within aircraft engines, deep space exploration instruments, space reentry vehicles, and down-well probes for oil and gas extraction. State-of-practice capabilities utilize commercial microelectronics optimized for lower temperature operations such as −20° C. to +120° C. The collective mechanisms causing degradation in performance of the existing standard electronics at high temperatures have failed to address this issue from a system perspective, with the intended outcome of enabling optimal performance at elevated temperatures. In particular, such modifications may degrade device performance at standard temperature ranges, making them unsuitable as an “all applications” product where the temperature range might be −20° C. to 500° C.

### SUMMARY

Existing microelectronic devices are incompatible with extreme temperature environments due to factors at the module, package, die, circuit, device, fabrication, and material levels. There are some challenges that are to be collectively resolved to enable microelectronics performance at extreme temperatures. The first challenge relates to charge transport characteristics of traditional materials degrading as operating temperature increases, resulting in lower efficiency and higher loss. In particular, electrically, the degradation stems from increased carrier scattering in conductors, increased charge trapping and current leakage in insulators, reduced charge density, and less mobile channel conduction. Further, impact on performance parameters in radio frequency (RF) and microwave devices (for example, HEMTs (High Electron Mobility Transistor), MIMCAPs (Metal-Insulator-Metal Capacitor), resistors, inductors, transmission lines) may result in substantial degradation of frequency dependance, impedance matching, and gain.

The second challenge relates to thermal conductivity of traditional materials that degrade as operating temperature increases, resulting in increased rates of circuit and device self-heating, with concomitant increases in RF and microwave noise. Further, thermal conductivity may relate to additional degradation in charge transport behavior of circuit elements due to self-heating. Another challenge includes thermally driven physical expansion within constituent materials (e.g., thin films) that alters film stress and strain from the as-deposited condition, which results in deviations in both charge transport and thermal conductivity characteristics. The next challenge includes a mismatch of thermally driven physical expansion behavior across interfaces of thin-film materials that results in degradation of charge transport both across and adjacent to layer interfaces.

Another challenge may be related to an increase of thermal noise as operating temperature increases. This reduces signal-to-noise ratio (SNR) of input and/or output signals, which thereby requires higher-power signals to be employed leading to increases in self-heating, compounding the situation. Another challenge may be the mechanical integrity of circuit packages, the die attachment, and signal input and output methods, including sub-mount integration methods that degrade as operating temperature increases, which results in less reliable, lower performance integrated RF/microwave modules.

In an embodiment, the disclosure relates to a use case of the system that includes specialized microelectronics for downhole sensing and power supply in oil extraction or mining operations. In such scenarios, sensors and power supply microelectronics may operate as part of a high-temperature system, in which operation itself contributes to thermal increase and there is no mechanism through which to reject heat or exert control over the environmental temperature. The prevalence of such scenarios may be rising as oil extraction grows increasingly complex, with deeper well bores and more impermeable surface materials more prevalent due to general exhaustion of simple oil sources. The ability to place microelectronics at the point of the bore may be significant for reducing sensor latency, increasing responsiveness, detecting potentially hazardous environmental conditions, and supplying optimal power to mechanical components. Temperatures in situ may reach above 300 degrees Celsius (300° C.) which may be associated with an excess of commercial tolerances of semiconductor microelectronics.

In an embodiment, the disclosure relates to a device that includes an integrated circuit die designed to function at a high temperature, wherein the integrated circuit die includes one or more HEMTs. The device includes at least a substrate, a package lid, a thermo-mechanical attachment layer and one or more microfabricated metal pillars. The substrate conveys incoming and outgoing signals to the integrated circuit die. The package lid encloses the integrated circuit die and is disposed on an opposite side of the integrated circuit die from that of the substrate. The one or more microfabricated metal pillars incorporate both thermo-mechanical pathways and signal pathways, and the one or more microfabricated metal pillars connect the integrated circuit die to the substrate.

In an embodiment, the disclosure relates to a system that includes one or more modules that are used in an environment subject to high temperature and interact via one or more incoming and outgoing signals with one or more other modules. The modules include an integrated circuit die designed to function at a high temperature, wherein the integrated circuit die includes one or more HEMTs. The device also includes at least a substrate, a package lid, a thermo-mechanical attachment layer and one or more microfabricated metal pillars. The substrate conveys incoming and outgoing signals to the integrated circuit die. The package lid is provided which encloses the integrated circuit die and is disposed on an opposite side of the integrated circuit die from that of the substrate. The one or more microfabricated metal pillars incorporate both thermo-mechanical pathways and signal pathways, and the one or more microfabricated metal pillars connect the integrated circuit die to the substrate.

In an embodiment, the disclosure relates to a device that includes an integrated circuit die designed to function at a high temperature, wherein the integrated circuit die includes one or more HEMTs. The device includes at least a substrate, a package lid, and an ablative carbon passiviation (ACP) thin film. The substrate conveys incoming and outgoing signals to the integrated circuit die. The package lid encloses the integrated circuit die and is disposed on an opposite side of the integrated circuit die from that of the substrate. The AFCP thin film ablates in response to elevated temperatures to release thermal energy and redeposits itself on an underside of the package lid.

In an embodiment, the disclosure relates to a method for making a device capable of operating in a high temperature environment. The method comprises fabricating the device as a plurality of layers on a bulk wafer. Once fabricated on a bulk wafer, the individual usable circuits are singulated from the bulk wafer. Each of the individual usable circuit are then tested in expected operating conditions and combined into one or more microelectronic modules for use in a high temperature environment. The device includes an integrated circuit die designed to function at a high temperature. The device includes at least a substrate, a package lid, a thermo-mechanical attachment layer and one or more microfabricated metal pillars. The substrate conveys incoming and outgoing signals to the integrated circuit die. The package lid is provided which encloses the integrated circuit die and is disposed on an opposite side of the integrated circuit die from that of the substrate. The thermo-mechanical attachment layer is placed between the integrated circuit die and package lid.

### BRIEF DESCRIPTION OF THE FIGURES

The detailed description is set forth below with reference to the accompanying figures. In the figures, the left-most digit(s) of a reference number identifies the figure in which the reference number first appears. The use of the same reference numbers in different figures indicates similar or identical items. The systems depicted in the accompanying figures are not to scale and components within the figures may be depicted not to scale with each other.

FIG. 1 illustrates an engineered system in a local environment, according to particular embodiments.

FIG. 2A illustrates a physical module that communicates outside of a local environment, according to particular embodiments.

FIG. 2B illustrates a physical module that communicates with another system within a local environment, according to particular embodiments.

FIG. 3A illustrates a view of a microelectronics module according to particular embodiments.

FIG. 3B illustrates a view of a microelectronics module set according to particular embodiments.

FIG. 4 illustrates an isometric view of a microelectronics packaging, according to particular embodiments.

FIGS. 5A and 5B illustrate transmission line structure, according to particular embodiments.

FIG. 5C shows a microphotograph of an implementation of a transmission line structure, according to particular embodiments.

FIGS. 6A-6C illustrate cross-section views of a microelectronics packaging according to particular embodiments.

FIG. 7A illustrates a preferred thermal management configuration.

FIGS. 7B and 7C illustrate a scanning electron micrograph of a thermal management material, according to particular embodiments.

FIGS. 8A and 8B illustrate a top-down view of a device with thermal measurement structures, according to particular embodiments.

FIG. 9 illustrates a diagram illustrating a preferred thermal management structure, according to particular embodiments.

FIGS. 10A and 10B illustrate techniques for post-processing of integrated circuits, according to particular embodiments.

FIGS. 11A and 11B shows a microphotograph of a curvilinear high-electron-mobility transistor (HEMT) mask layout embedded in a co-planar waveguide (CPW), according to particular embodiments.

FIGS. 11C and 11D show a performance plot illustrating the behavior of the devices in FIGS. 11A and 11B, according to particular embodiments.

FIGS. 12A-12C illustrate cross-section views of device, according to particular embodiments.

FIGS. 13A and 13B illustrate a cross-sectional diagram of a semiconductor, according to particular embodiments.

FIGS. 14A-14C illustrates a cross-section view of a GaN HEMT structure, according to particular embodiments.

FIGS. 15A-15C illustrate a schematic of a sectioned stress-relaxing passivation (SSRP) feature trench-etched into microelectronic cells, according to particular embodiments.

FIGS. 16A-16C illustrates a cross-section view of a passivation layer employing specialized material selection and device architectures, according to particular embodiments.

FIG. 17 illustrates a flow diagram of an example method for manufacturing a device, according to particular embodiments.

### DETAILED DESCRIPTION

In the drawings and descriptions that follow, like parts are typically marked throughout the specification and drawings with the same reference numerals. The drawing figures are not necessarily to scale. Certain features may be shown exaggerated in scale or in a somewhat schematic form and some details of conventional elements may not be shown in the interest of clarity and conciseness. The present disclosure is susceptible to embodiments of different forms. Specific embodiments are described in detail and are shown in the drawings, with the understanding that the present disclosure is to be considered an exemplification of the principles of the disclosure and is not intended to be limiting to that illustrated and described herein. It is to be fully recognized that the different teachings of the embodiments discussed below may be employed separately or in any suitable combination to produce desired results. Features and characteristics described in more detail below that are readily apparent to those skilled in the art upon reading the following detailed description of the embodiments and by referring to the accompanying drawings.

Unless otherwise noted, the term “extreme temperature electronics” refers to analog and mixed-signal electronics designed for operation at temperatures in excess of 300° C. and the various active devices, passive devices, packaging, bonding and braising materials, inductors, transmission lines, direct current bias lines, contact pads, ground planes, their architectures, topologies, and the material layers comprising them. The term “extreme temperature electronics” may also be used to describe specialized process flows for material treatment, device fabrication, circuit design, radio frequency, and direct-current electrical testing used in the creation of said electronics. As used herein, the terms “high temperature” and “extreme temperature” mean temperatures in excess of 300° C.

In some examples, other terms include, but are not limited to, Monolithic Microwave Integrated Circuit (MMIC) that may be associated with a type of integrated circuit that operates at microwave frequencies between 300 MHz to 300 GHz to perform a range of functions. In some examples, the MMICs may be comprised of RF such as microwave circuit blocks that have been fabricated monolithically on the same substrate for operation across a range of frequencies. In other example, other arrangements are possible where circuit blocks may be fabricated separately and combined into an assembly. The RF and/or microwave circuit blocks are analog circuits such as low-noise amplifiers, high-power amplifiers, radio frequency (RF) switches, delay lines, attenuators, filters, mixers, and RF power splitters, dividers, and combiners, which may be integrated together. The MMICs include Field Effect Transistors (FETs) such as High Electron Mobility Transistor (HEMT). HEMTs are FETs that rely on a Two-Dimensional Electron Gas (2DEG) layer channel with ohmic contacted source and drain electrodes flanking a Schottky contacted gate that modulates the electrical conductivity of the underling channel region to control the flow of charge carriers between the other electrodes. The FETs and/or HEMTs rely on a heterojunction interface between different energy bandgap materials, rather than on impurity doping to modulate the electrical conductivity of a channel region, 2DEG may relate to a region that emerges within transistor architectures between boundary layers of materials with differing bandgap energies, resulting in the free movement of electron gas within two dimensions. Schottky Barrier and Ohmic Contact may be defined as a potential energy barrier for electrons formed at the junction of metal and a semiconductor material. The Schottky Barrier conducting current in two directions is known as an Ohmic Contact. Gallium Nitride (GaN) may be a binary III-V direct bandgap semiconductor commonly used in transistors to improve operation at higher temperatures and voltages, and Aluminum Gallium Nitride (AlGaN) may be a semiconductor material commonly grown on GaN to form heterojunctions, or interfaces between two materials of unequal band gaps.

There is a need for design, fabrication, testing, packaging, integration, and subsequent operation of a system that enables operation in extreme temperatures (T≥300° C.). The present disclosure discloses systems that include microelectronics which are modified to operate in extreme temperatures at various levels including, but not limiting to, system-level, wafer and die-level, circuit level, device level, fabrication, and material level.

The system-level may relate to an engineered system within a local environment characterized by extreme temperature excursions exceeding T≥300° C. The system performs one or more functions through the use of modules. Functions may include receiving, storing transmitting, and reacting to signals. In many cases, the modules may contain microelectronics that fulfill the intended function while operating at extreme temperatures and without the ability to control thermal attributes of their local environment. In one embodiment, the local system boundaries may be defined by temperature gradients T≥25° C. The wafer or die level may relate to manufacturing of circuits that relies on the use of raw wafers, including active semiconducting materials from which transistors are formed, hosted on an underlying bulk material that typically provides both mechanical and thermal constraints for the circuits that may be formed on the material.

The circuit level includes low-noise amplifiers, high-power amplifiers, radio frequency (RF) switches, delay lines, attenuators, passive and active filters, mixers, and RF power splitters, dividers, and combiners. In an embodiment, engineered behavior of such analog circuits may be characterized by the corresponding response to bias voltages, input and output RF power levels, signal frequency and bandwidth, environment temperature, noise behavior, and stability. For device-level scenario, some multiple basic devices may be needed to construct a circuit, including active elements (for example, transistors) and passive elements such as capacitors, inductors, resistors, transmission lines, direct current bias lines, contact pads, and ground planes, integrated together and fabricated monolithically on the same wafer substrate.

In one embodiment, individual wafers, or multi-wafer lots, experience the conditions of the circuit fabrication process at the same time, allowing for high throughput manufacturing of the same (or similar) circuits. Upon completion of fabrication and subsequent on-wafer validation testing, individual usable circuits may be singulated from the bulk wafer. The die-level devices are then available for incorporation into packages that may be integrated into modules for use in system applications. The circuit level may be related to analog front-end circuits that may require enabling signal function modules within systems operating at extreme temperatures.

The fabrication-level may be related to fabrication of active and passive devices into circuits, integrated monolithically as multiple dies on a wafer substrate, which may be accomplished by the interspersed growth and/or deposition of thin films of materials and their lithographic patterning for removal of film material via wet or dry etching or via liftoff methods. Upon completion of fabrication, individual die may be singulated from the host wafers using any of a number of different methods common to the industry. The material level may include layered materials comprising an integrated circuit that may exhibit different electrical, thermal, optical, chemical, and mechanical behaviors based on physical composition and fabrication process parameters selected during their construction. In an embodiment, exposure to extreme operating temperatures contributes not only to changes in the individual layer physical properties, but also gives rise to emergent behaviors as a consequence of the physical juxtaposition of these heterogenous layers with different dependencies on environmental temperature.

However, the various aspects may be implemented in many different forms and should not be construed as limited to the implementations set forth herein. The disclosure encompasses variations of the embodiments, as described herein. Like numbers refer to like elements throughout.

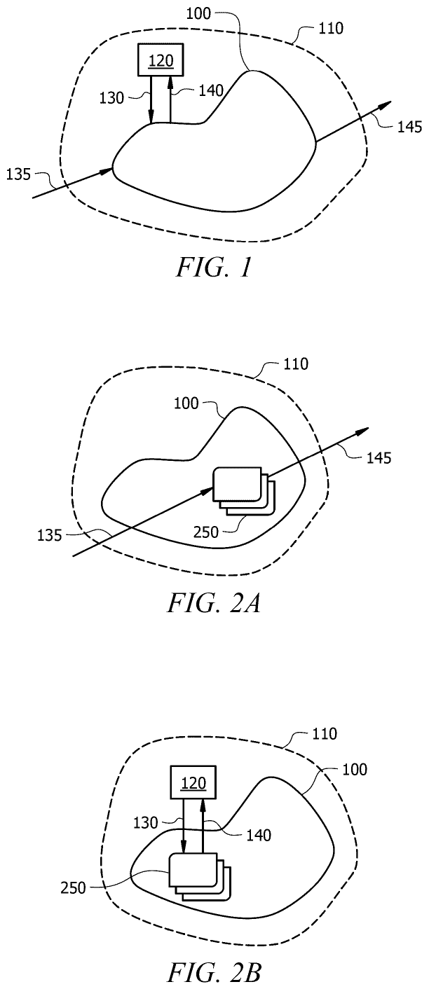

FIGS. 1-4 define contextual relationships relevant to the methods and configurations disclosed in this specification. These relationships extend between the environment, engineered systems that operate within that environment, modules that implement those systems, and microelectronics incorporated into those modules.

Referring initially to FIG. 1, an engineered system (100) is shown operating in a local environment (110). The environmental characteristics of the local environment (110) in at least some embodiments may not be controlled by the engineered system (100). The engineered system (100) may perform functions within the local environment (110). As a non-limiting example, the local environment (110) may be characterized by extreme temperatures (T≥300° C.), and the local environment (110) may also be characterized by a temperature gradient within its extent, in which reside one or more other local systems (120) at temperatures differing by ΔT≥25° C. from the engineered system (100).

In particular embodiments, the engineered system (100) performs functions that may include sensing, receiving, storing, and/or reacting to incoming local signals (130) originating from other local systems (120) within the local environment (110), as well as sensing, receiving, storing, and/or reacting to non-local incoming signals (135) that originate outside of the local environment (110). In particular embodiments, other functions of the engineered system (100) may include sensing, generating, storing, and/or providing outgoing local signals (140) to act on other local systems (120), as well as generating, storing, and communicating non-local outgoing signals (145) beyond the local environment. The incoming local signals (130) and non-local incoming signals (135) may be electrical, optical, thermal, chemical, or mechanical in nature. Similarly, the outgoing local signals (140) and non-local outgoing signals (145) may also be electrical, optical, thermal, chemical, or mechanical in nature.

In particular embodiments, functions of the engineered system (100) may be accomplished electrically using microelectronic integrated circuits (ICs). Example types of ICs may include analog, mixed-signal, and digital circuits. Example classes of analog circuits may include high-frequency (HF), radio frequency (RF), microwave, mm-wave, or quasi-optical operating frequencies. In particular embodiments, the ICs may take the form of Monolithic Microwave Integrated Circuit (MMIC) that may be associated with a type of integrated circuit that operates at microwave frequencies between 300 MHz to 300 GHz. A MMIC is a type of integrated circuit that typically performs functions such as microwave mixing, power amplification, low-noise amplification, and high-frequency switching. These devices are dimensionally small and may be mass-produced.

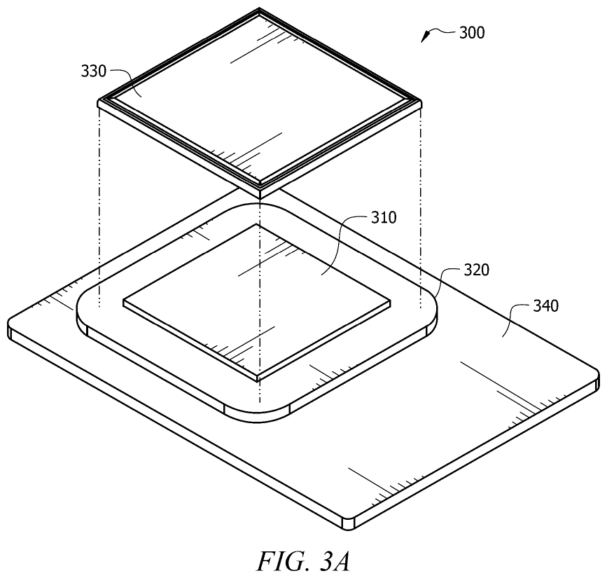

FIGS. 2A and 2B illustrate an exemplary operational diagram, in which the system may perform a function using one or more modules (250) located within the engineered system (100), according to particular embodiments. In particular embodiments, some functions may be performed by the engineered system (100) that are realized using the one or more modules (250) located within the bounds of the engineered system (100) and subject to the local environment (110). The one or more modules (250) may comprise one or more microelectronic integrated circuits (ICs), that form, for example, analog, mixed signal, and digital circuits. The one or more ICs may be characterized in particular embodiments as operating in frequency ranges that include one or more of the bands commonly referred to as high-frequency (HF), radio frequency (RF), microwave, mm-wave, and quasi-optical.

The driving functional requirements for the one or more modules (250) may provide defined interactions with non-local incoming signals (135) and non-local outgoing signals (145) as shown in FIG. 2A. As shown in FIG. 2B, the driving functional requirements for the one or more modules (250) may provide defined interactions with incoming local signals (130) and outgoing local signals (140). The one or more modules (250) may be able to communicate with non-local signals, local signals, or any combination of signals for both with in the local environment (110) and outside of it.

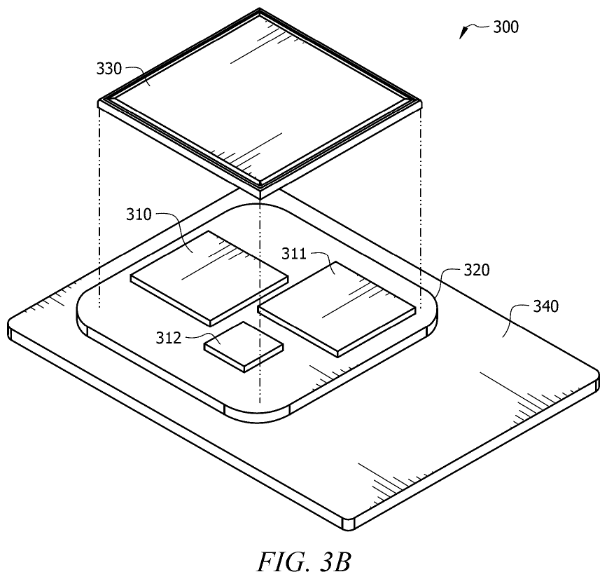

One or more modules (250) may also satisfy operating constraints stemming from electrical, thermal, chemical, mechanical, and geometric characteristics of the engineered system (100) as well as the local environment (110). As a non-limiting example, the system may include one or more modules (250) located within the engineered system (100) that communicates via incoming local signals (130) and outgoing local signals (140) with another local system (120) within the local environment (110). The local environment may have a different ambient temperature relative to the engineered system (100) (e.g., ΔT≥25° C. relative to the engineered system (100)). As a non-limiting example, the local system (120) may include one or more sensors (e.g., temperature, pressure, electrical, optical, and the like) communicably coupled to the one or more modules (250) via the incoming local signals (130). The one or modules (250) may be modified to function in the local environment (110) and with the ΔT≥25° C. as will be described next, in more detail, with regards to FIGS. 3-16.

FIG. 3A illustrates a view of an exemplary microelectronics module (300) that includes a mounted RF or microwave analog integrated circuit (IC) die (310), according to particular embodiments. In one or more embodiments the microelectronics module (300) may be similar to the one or more modules (250) shown in FIGS. 2A and 2B. In an embodiment, FIG. 3 shows a microelectronics module (300) that operates under extreme temperatures within the engineered system (100) and may include specialized packaging methods to convey incoming and outcoming signals between substrates (320) and integrated circuit die (310).

In some embodiments the one or more modules (250) may include a mounted microelectronics module (300) that includes RF or microwave analog IC parts. The microelectronics module (300) includes an IC die (310) affixed within an enclosed IC package that includes a substrate (320) and a lid (330). The microelectronic module (300) and its constituent parts are configured to satisfy electrical, thermal, chemical, mechanical, and geometric constraints of a sub-mount (340) and the local environment (110). The lid (330) is disposed on the opposite side of the IC die (310) from that of the substrate (320). The substrate (320) may be differentiated from the lid (330) in that the substrate (320) may be associated with the primary functions of both conveying of incoming and outgoing signals to and from the IC die (310), while the lid (330) may be associated with the primary function of the mechanical containment of the IC die (310) and thermal interface with the sub-mount (340). The microelectronics module (300), optionally, may include multiple dies (not shown) that are hosted on an active or passive interposer within the package or alternatively in a 3-D stacked die configuration within the package.

Both the substrate (320) and lid (330) provide a thermal interface with the sub-mount (340). If the sub-mount (340) has a temperature difference ΔT≤25° C. relative to the temperature of the engineered system (100), then the sub-mount (340) may be considered to be a co-element of the engineered system (100), together with the microelectronics module (300). If, however, the sub-mount (340) has a ΔT≥25° C. relative to the engineered system (100) then the sub-mount (340) may be regarded as a separate local system (120) within the local environment (110). Considering this arrangement, the sub-mount (340) provides a natural location for separating analysis of the engineered system (100) from its constituent one or more modules (250).

Current microelectronics modules rely on large heatsinks to dissipate heat but heatsinks have limited efficiency beyond typical operating temperatures and add bulk to the microelectronic module (300), making packaging complex. Current microelectronics solutions may likewise be used to provide passivation to protect circuits from a broad spectrum of environmental contamination. Contamination examples may include exposure to high humidity, particle contamination, and mild chemical exposure. Thus, a need exists for a method to provide both passivation and thermal management sufficient to enable microelectronics that are capable of handling extreme operating temperatures.

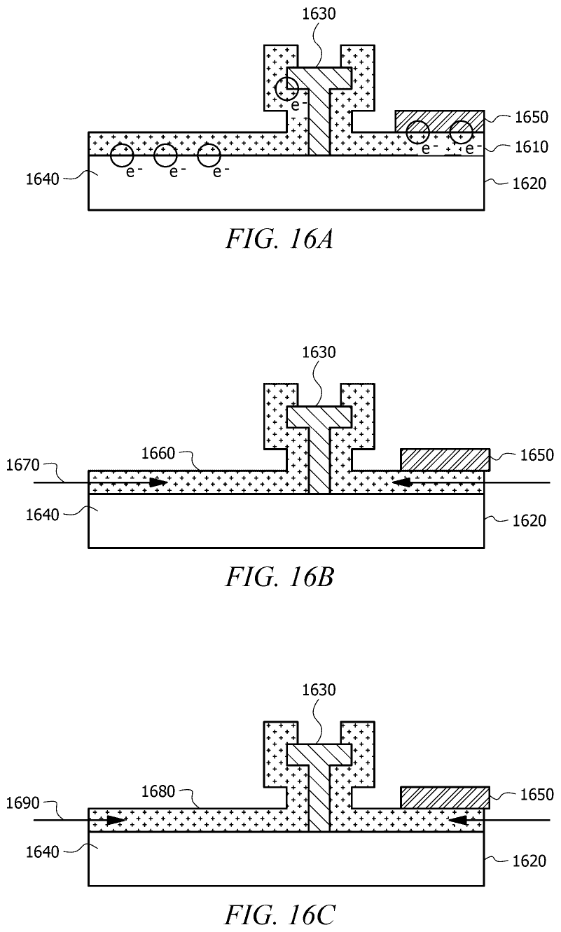

FIG. 3B illustrates a view of an exemplary microelectronics module (300). As illustrated, the microelectronics module (300) includes IC die (310), IC die (311), and IC die (312). In other examples, the microelectronics module (300) may include more or few dies. The dies (310, 311, 312) may be individually fabricated in the same or different process flows, as discussed below in relation to FIG. 17. The dies (310, 311, 312) may be electrically coupled to one another via a common carrier, e.g., an interposer, or substrate (320).

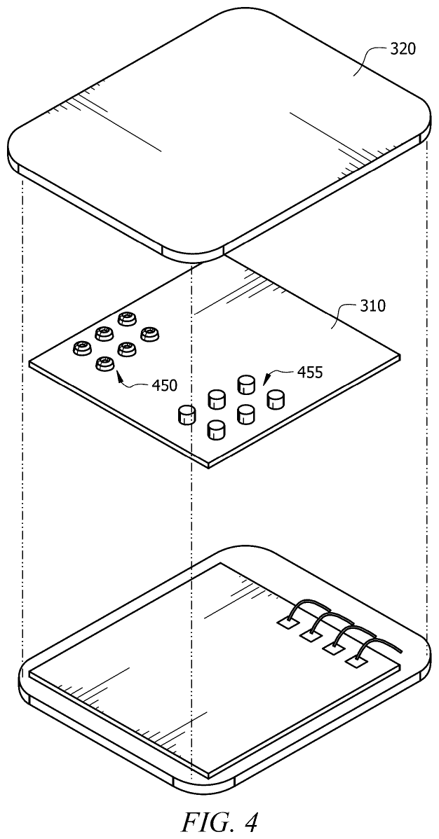

FIG. 4 illustrates an isometric view of a microelectronics packaging that may be utilized within a microelectronics module (300) to provide communication between a substrate (320) and an IC die (310), according to particular embodiments. In some examples, the present disclosure may be associated with methods that may include scenarios where the active side of the IC die (310) faces the plane of the substrate (320), referred to as “flip-chip” packaging, or configurations that rely on solder bump bonds (450) or metal interconnect pillars (455) to communicate electrical signals between die and substrate.

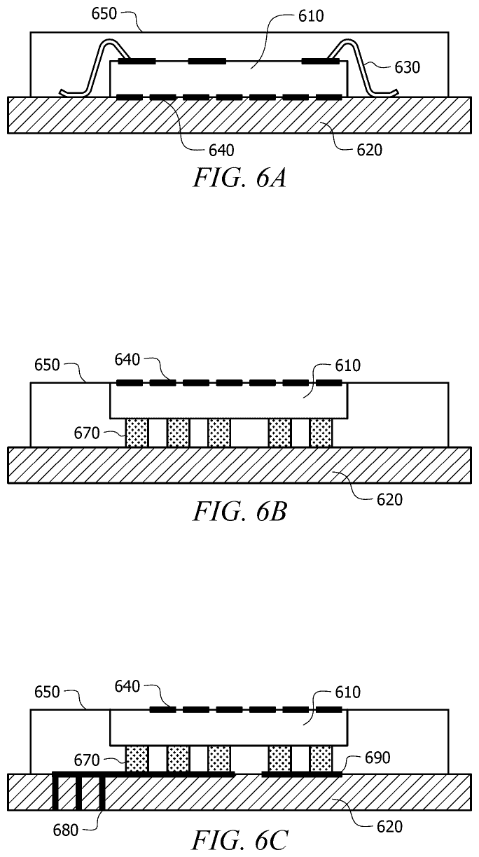

In one or more embodiments the metal interconnect pillars (455) may incorporate both thermo-mechanical pathways and signal pathways as will be described below with regards to FIG. 6B. This configuration allows the IC die (310) to extract heat away from the IC die (310) to the substrate (320), while still allowing the IC die (310) to communicate with the substrate (320) and then to communicate outside the engineered system (100).

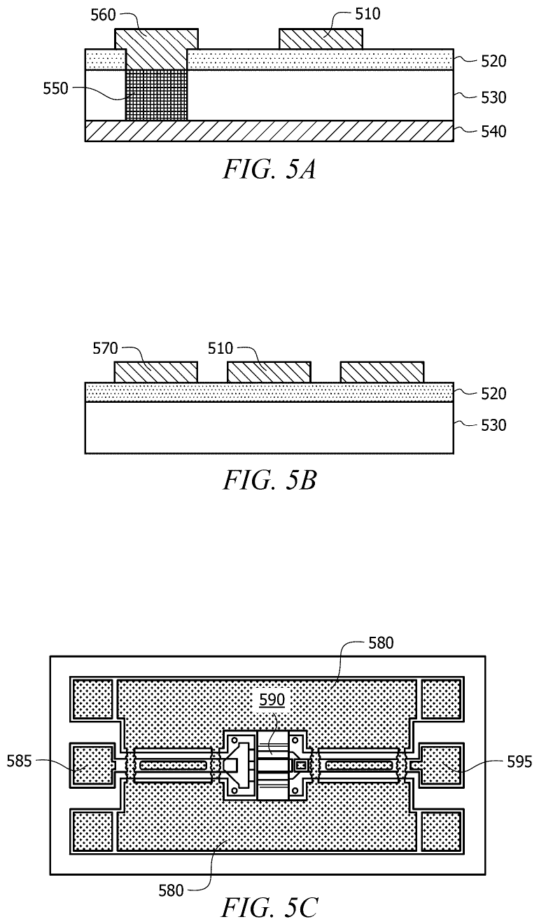

FIG. 5A illustrates a cross-sectional schematic of a microelectronics module (300) and method for packaging the IC die (310). A packaging method includes construction of impedance-controlled signal interconnects within an IC die (310), such as an MMIC die as an enabling element within a microelectronics module (300). For example, the microelectronics module (300) may function as an RF circuit that may function at extreme temperatures. The use of co-planar waveguides allows for the circumvention of through substrate vias, thereby eliminating a critical failure mode in RF circuit operation at the die level.

Microstrip transmission lines may be the standard method for constructing impedance-controlled signal interconnects within ICs such as a MMIC. In an example, one microstrip approach uses through substrate vias (TSV) elements (550) to allow low-resistance connection between in plane traces (560), a die surface (520), and a conductive ground plane (540) on the backside of an IC substrate (530). In plane traces (560) allow electrical connections to point within the front-side IC substrate requiring ground potential such as shunt capacitors, transistor electrodes, etc. Using this microstrip configuration, high-frequency waveforms may propagate signal line (510) under controllable, predictable impedance conditions. Using this microstrip configuration, high-frequency waveforms may propagate between signal line (510) and the ground plane (540) under controllable, predictable impedance conditions.

However, at extreme high temperatures, the mismatch in coefficient of thermal expansion (CTE) between the IC substrate (530) and conductive materials filling and/or lining the TSV elements (550) creates a performance degradation and/or potential failure mode. Specifically, stress mismatches forming between the different materials of the substrate and via fill may lead to fracture, delamination, and/or morphological inhomogeneities which give rise to electrical resistance variations and/or increases in ground potential within the circuits on the front side of the substrate. This failure mechanism is compounded by the presence of material interfaces on not just one boundary of the TSV elements (550), but around the entire periphery of the TSV elements (550). As an example, the CTE of a SiC substrate (530) is 2.7×10⁻⁶/° C., while the typical TSV fill material of both gold or copper have a more than 5× larger CTE at 14.1×10⁻⁶/° C. and 16.7×10⁻⁶/° C., respectively. This CTE mismatch failure mechanism is compounded by the presence of material interfaces on not just one boundary of the TSV, but around the entire periphery of the TSV element (550).

In FIG. 5B, a construction is disclosed that is designed to circumvent use of a TSV element (550) and hence the associate failure mechanisms at high temperatures, and high frequency waveforms propagate on signal lines (510) under controllable, predictable impedance conditions using reference ground structures provided by in-plane traces (560).

FIG. 5B illustrates a cross-sectional schematic of the specialized microstrip designed to circumvent use of TSVs, according to particular embodiments. As shown in FIG. 5B, in one or more embodiments, the IC substrate (530) does not include TSV elements (550, FIG. 5A). Instead, the microelectronics module (300) is designed to include a plurality of additional signal lines (570) in addition to signal line (510), eliminating the problems associated with the TSV element (550) and in-plane traces (560). The additional signal lines (570) are adjacent to the signal lines in an impedance-controlled coplanar waveguide (CPW) structure that still permits the extraction of heat from the backside of the IC substrate (530). This is shown in more detail in FIG. 5C which shows a view of one embodiment of this configuration as a fabricated AlGaN/GaN HEMT device (590) embedded in an impedance controlled CPW structure with signal lines (585) and (595) and ground traces (580) without use of TSVs. The AlGaN/GaN HEMT device (590) may provide higher power density and breakdown voltage then other HEMT type devices. By including additional signal lines (585) and (595), the problems with TSV element (550) may be avoided and the AlGaN/GaN HEMT device (590) may operate at higher temperatures.

FIG. 6A illustrates a configuration of microelectronics module (300) that includes an IC die (610) such as a MMIC die, a substrate (620), and a lid (650). In some embodiments, the MMIC devices, such as high-power amplifiers (HPAs), generate significant self-heating during RF operation. One configuration of the microelectronics module (300) uses a face-up IC die (610) attached to a substrate (620) through a thermo-mechanical attachment layer (640) with wire bonds (630) employed to convey signals from the substrate to the die hosting the MMIC. A package lid (650) encloses the assembly. However, this configuration does not allow for heat energy to be efficiently removed from the top surface of IC die (610).

FIG. 6B illustrates a cross-section view of microelectronics module (300) that, instead of using a face-up IC die (610), uses a face down IC die (610), in accordance with a particular embodiment. The packaging, of the microelectronics module (300) in an embodiment shown in FIG. 6B, is configured such that both the thermo-mechanical and signal pathways are part of a single structure: microfabricated metal pillars (670). The microfabricated metal pillars (670) are situated between the package substrate (620) and face-down IC die (610) and provide the function that was provided by the wire bonds 630 in FIG. 6A as well as thermal conductivity between the IC die (610) and the package substrate (620). As a non-limiting example, the microfabricated metal pillars (670) and/or the thermo-mechanical attachment layer (640) may be formed using an Au—Sn solid-liquid interdiffusion bonding process that is used to provide conductive attachment pillars that remain robust at temperatures T>300° C.

This configuration allows the backside die thermo-mechanical attachment layer (640) to be used for additional heat extraction via the package lid (650). A thermo-mechanical attachment layer (640) may be provided across the back of the IC die (610) and may take a similar form to that used in FIG. 6A between the IC die (610) and the package substrate (620).

FIG. 6C discloses another aspect of the configuration of FIG. 6B, by explicitly showing how conductive interconnect layers (680) in the package substrate (620) are used to communicate signals and power to the next higher level of the assembly. This configuration may also be used to obviate the necessity of air-bridges, which are less desirable for flip-chip die attach configurations such as in FIG. 6B. Specifically, the package substrate interconnect layers (690) may form a substitute for circuit structures typically implemented in an air-bridge construction, such as inductor coils, inductor crossovers, as well as in distributing ground potential across the sources electrodes for RF HEMT architectures comprised of more than two gate fingers.

Other additional techniques and structure may be used in the microelectronics module (300) to provide improved extreme temperature survivability and thermal management of the microelectronics module (300). One such technique is the incorporation of a one-time-use sacrificial ablative layer inside the microelectronic module (300) package.

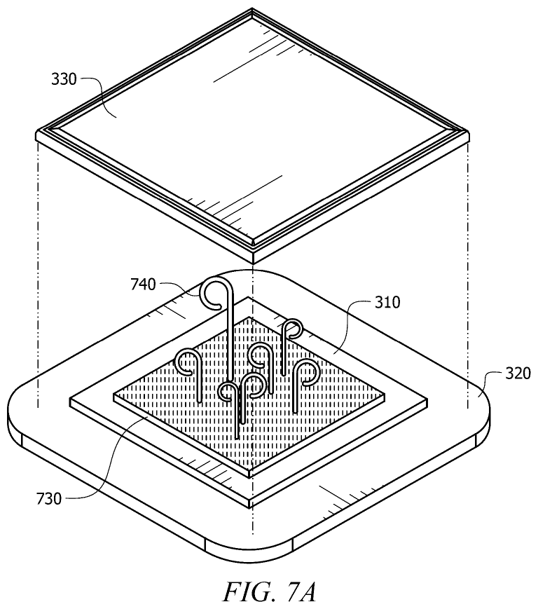

FIG. 7A discloses a thermal management construction consisting of a passive coating layer (730) for improved management of self-generated heat via ablation (740) in comparability with face-up part attachments, for example, as shown in FIG. 6A. Specifically, FIG. 7A shows an applied passive coating layer (730) with a composition such that it may undergo a one-time ablation in response to local heating on the part, resulting in the transferal of both mass and heat through ablation (740) from the attached IC die (310) onto the underside of the package lid (330), thereby slowing the rate of die self-heating until the coating is exhausted. In essence, passive coating layer (730) sublimates from the surface of the IC die (310), releasing thermal energy, and redeposits itself on the underside of the package lid (330), effectively cooling the IC die (310) in a one-time process due to its latent heat of vaporization, transferring heat from the IC die (310) to the lid (330).

As one, non-limiting example, passive coating layer (730) utilizes a carbon fullerene (C-60) composition, prepared, and deposited under parameters chosen to target the onset and duration of ablation at different local on-die temperature ranges (e.g., 250° C. and higher). Referred to as an ablative carbon passivation (ACP), passive coating layer (730) is non-electrically conductive and does not interfere with normal circuit or package performance before, after, or during sublimation or ablation (740).

FIGS. 7B and 7C illustrate a low magnification and a higher magnification scanning electron micrograph of prepared Ablative Carbon Passivation (ACP) thin film, respectively, according to particular embodiments.

The ACP layer (710) may be non-electrically conductive and may not affect circuit or package performance before, after, or during sublimation. In an example, the ACP morphology may be associated with electrically isolated individual grains (720) that form a discontinuous passivation layer that may be a poor electrical conductor (insulator) while remaining thermally conductive. The nanometer size nodes (≈100 nm sized) heat up and ablate more readily than a continuous carbon film. The ablation process of the ACP film provides a measure of thermal management for the underlying microelectronic by relying on the phase change of the ablated C-60 as a supplement to gradient-driven thermal transport through other paths within the package die. The benefits of this process may extend until the ACP layer is consumed.

In an embodiment, a C-60 carbon nanoparticle source may be used to thermally evaporate the ACP layer (710) onto a surface of the IC die (310) during fabrication in a vacuum chamber. The source material may be placed in a crucible and heated to approximately 440° C. at a pressure of approximately 2.5 millitorr (mTorr) to thermally evaporate it. The microcircuit may also be placed in the vacuum chamber in line with the source evaporation. This evaporation deposit forms the ACP film. In an embodiment, depending on the composition and deposition parameters, the film may be tuned to target ablation at different extreme temperature ranges (e.g., T=300-500° C.).

The development of extreme temperature MMIC technology requires the ability to monitor the local on-die temperature behavior within RF and microwave HEMT circuits when operated under target bias and power conductions, while exposed to extreme temperature environments. This in-situ monitoring capability supports both validation of device and circuit predictive models, as well as the performance assessment of design elements included for thermal management, the effect of packaging, and the overall performance of RF modules such as the one or more modules (250). Existing monitoring techniques rely upon external sensing methods to derive the junction temperature.

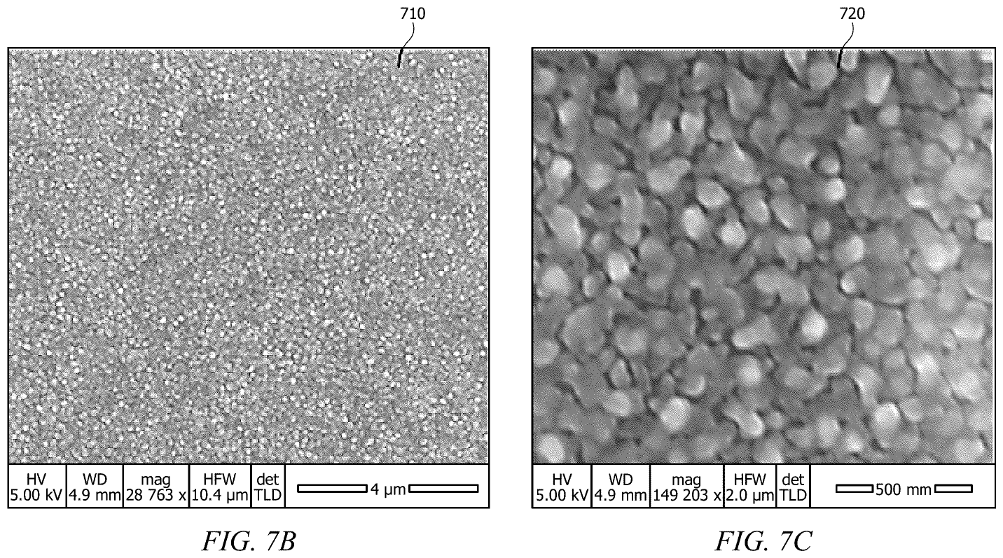

FIG. 8A shows a top-down view of an example of a physical layout depicting a technique that relies on indirect sensing circuits to derive the HEMT junction temperature, where additional two pairs of wires (831) and (832) are placed nearby a first contact (825) and used to make a 4-point measurement of local resistance to enable the indirect inference of the temperature in the HEMT channel based on a pre-calibrated lookup table.

FIG. 8B illustrates a top-down view of an auxiliary structure for measuring transistor gate temperatures of an integrated circuit, according to particular embodiments. In certain embodiments, the HEMT or other device may include the auxiliary structure.

Self-heating in RF circuits is driven largely by high carrier densities in the HEMT channel region, (for example, under high-power amplification). The microelectronic modules (300) may be fabricated to incorporate an auxiliary structure for measuring transistor gate temperatures of integrated devices in the IC die (310) such as an HEMT circuit. While signals applied to HEMT gate (830) modulate a conductive channel in the underlying semiconductor (805) to control the connection between the source (810), gate (840) and drain (811), within the same device structure is included to allow for a resistance measurement between contacts at each end: first contact (825), second contact (850) and a dummy gate (835).

The dummy gate (835) may be constructed with known geometry and material composition within the HEMT circuit, and its resistance change is monitored to obtain the absolute temperature. Based on the length, cross-sectional area, and compositional makeup of the dummy gate (835), a precomputed resistance as a function of temperature may be calculated and used as a calibration to directly measure the temperature in the gate region of the operational HEMT. The measurements may include the time evolution of the local temperature within the circuit and the overall steady-state temperature of the system, which may be achieved during the duration of circuit operation.

Considering the challenges of producing a single MMIC die or other IC dies (310) as well as its packaging that delivers constant performance across wide ranges of environmental operating temperatures (e.g., T=25° C. to T=500° C.), one alternative may be related to fashion a microelectronic module (300) that effectively covers wide temperature ranges by incorporating multiple IC and/or MMIC technologies internally. In this way, the microelectronics module (300) may adapt to temperature changes by self-tuning and switching between subcircuits IC dies (310), each optimized for different operating temperature ranges. For example, in a non-limiting example, separate Transmit and Receive (T/R) modules optimized for low, medium, and high temperatures operation may be designed and integrated onto a single substrate.

In some embodiments, multiple basic devices may be used to construct a microelectronics module (300), including active elements (i.e., transistors) and passive elements such as capacitors, inductors, resistors, transmission lines, de bias lines, contact pads, and ground planes, integrated together and fabricated monolithically on the same wafer substrate. As an example, specialization of device topology and architectures may be employed to reduce thermal stresses within the device, facilitating sustained operation at extreme temperatures. These specialized design features result in specialized process flows supporting their fabrication.

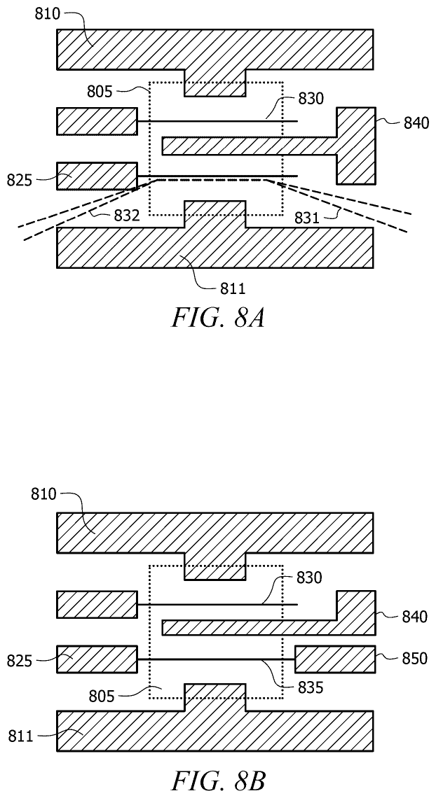

FIG. 9 illustrates an electrical schematic (900) providing redundancy into integrated circuit designs to address circuit performance considerations stemming from operation in extreme temperature environments, according to particular embodiments. This method employs a single microelectronics module (910) incorporating two or more ICs (920, 930, 940) such as a plurality of MMICs, each of which may be configured to satisfy performance requirements over a different operating temperature range. In use, an off-module controller (970) determines which of the two or more ICs (920, 930, 940) may be activated depending on the real-time temperature range experienced by the microelectronics module (910). The real-time temperature range may be determined by the off-module controller (970) by making a real-time measurement of the operating temperature within the local environment (110). Microelectronics module (910) input signal (950) may be acted on by a single IC (e.g., 920) selected by the controller (970), such that microelectronics module output (960) is determined by that same selected IC (e.g., 920). In practice, a low-temperature traditional technology IC (e.g., 920) may be selected by the controller (970) for the microelectronics module (910) to provide signal functions to a system with a normal temperature environment (e.g., T<125° C.). In this example, if the temperature environment exceeds T=125° C., a different IC (e.g., 930) may be selected by the controller (970) which, by its design and fabrication, is tailored to provide temperature performance better matched than the traditional IC (e.g., 920). In this manner, multiple operating temperature ranges may be accommodated over a gradient of temperatures reaching extreme conditions (e.g., T≥300° C.).

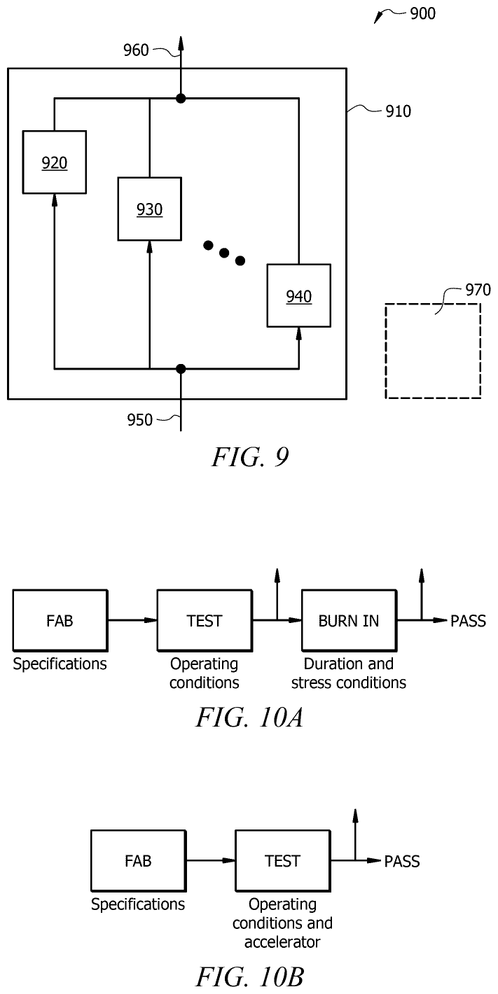

FIGS. 10A and 10B illustrate techniques for post-processing of microelectronics modules (300) and/or IC dies (310) for the purpose of optimizing their performance at extreme operating temperatures (T≥300° C.), according to particular embodiments. In an embodiment, a method is disclosed to optimize the one or more modules (250) performances at extreme temperatures at the circuit level which may be a technique for post-processing of IC dies (310). The compressive or tensile stress of a thin deposited or grown film depends on the material composition, geometry, and environment (mechanical and thermodynamic).

As a non-limiting example, one strategy for optimizing the charge transport behavior of microelectronics modules (300) such as GaN RF microelectronics under extreme operating temperatures, is to subject newly fabricated circuits to a burn-in step. Under burn-in, electrical bias or local environmental (110) temperature conditions may be applied prior to use, to create non-reversible physical changes in the microelectronics module (300). Such changes may include the engineering of layer morphology or charge pinning behaviors that result in charge transport behaviors at target temperatures that differ from the behavior that may be encountered without such post-fabrication treatments. Design of so-called “burn in” techniques may be accomplished by using a design-of-experiments approach under which a set of samples is created using an N-dimensional array of fabrication process parameter values. By subjecting such samples to a similar N-dimensional array of electrical and temperature exposure conductions, correspondence may be obtained that maps the dependance on fabrication parameters to RF MMIC characteristics.

In an embodiment as shown in FIG. 10A, use of burn-in techniques may begin after completing fabrication according to a process flow specification, and validation testing may be performed under expected operating conditions. After testing, a burn-in process may be undertaken to accelerate the failure of weak components by subjecting samples to burning in stress conductions beyond the targeted operating conductions. In an embodiment, exposing samples may relate to burn-in for sufficient duration exercises failure mechanisms that enable the pass-fail binning of lower lifetime parts not apparent during standard test screening.

Alternatively, as shown in FIG. 10B, after completing fabrication according to a process flow specification, a test procedure may be undertaken to validate operation under target operating conductions. However, the test procedure may be recognized to simultaneously contribute towards acceleration of part lifetime. In these embodiments, rather than viewing this as accelerated aging, non-reversible effects due to exposure to accelerator conditions may be considered an element of preparation of the microelectronic module (300) for future use.

For active devices, such as RF, MMIC and other types of microelectronics modules (300), temperature-driven effects, like maximum current and forward gain, are largely reversible upon cooling to standard operating temperatures of 40° C. Above 300° C., thermo-electro-mechanical stresses in constituent transistor materials, particularly at the gate and channel interface, create increasingly non-reversible effects that rapidly degrade device and/or circuit performance. The temperature-driven strain forming from a linear gate may be uniformly applied to the crystal axis of the underlying epitaxial materials.

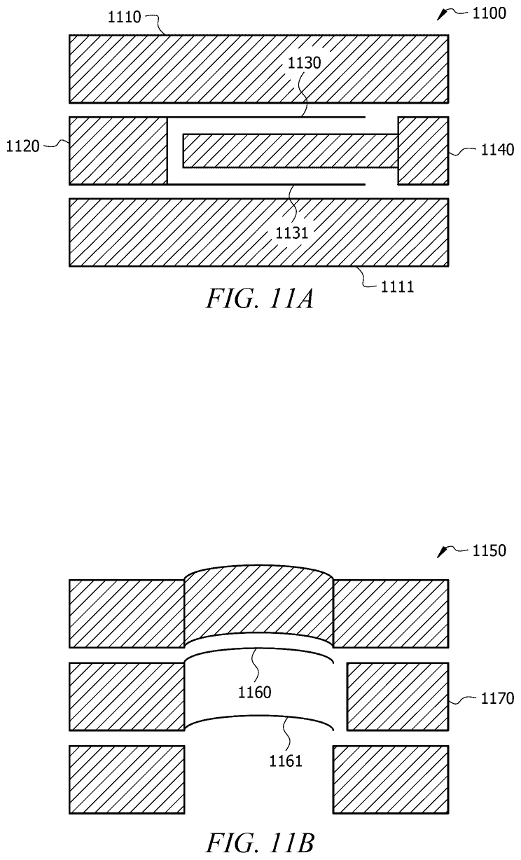

FIG. 11A illustrates a top-down view of a curvilinear high-electron mobility transistor (HEMT) mask layout embedded in a co-planar waveguide (CPW). Inline RF transistors (1100) may use multi-finger gates that are associated with parallel linear patterns of gate material sharing a common source and common drain. With impedance control provided by co-planar ground planes (1110) and (1111), RF signals are introduced via a Coplanar waveguide (CPW) center conductor (1120) onto a two-finger gate structure formed by (1130) and (1131). With the appropriate basing of the HEMT, signals applied to the gates may populate carriers in the 2DEG layer within the underlying semiconductor and an output RF signal may develop on the drain electrode (1140) suitable for propagation to the next circuit element.

FIG. 11B illustrates a top-down view of a curvilinear high-electron mobility transistor (HEMT) mask layout embedded in a co-planar waveguide (CPW), used to decompose interface strain into components orthogonal to the underlying channel crystal, according to particular embodiments. A specialized design may be disclosed for transistors incorporates of a curvilinear gate architecture (1150) to spread thermal strain in directions not aligned with the underlying semiconductor crystal axis, reducing the overall impact on the 2DEG channel under the gate. By spreading the forces arising from strain in the films, sensitivity to temperature may be reduced. While the gate material may be typically polycrystalline, the underlying semiconductor hosting the transistor channel may be crystalline. This difference in material structure between the gate and channel may be exploited to engineer the behavior of the interface when the gate or channel structure may be subjected to extreme operating temperatures by altering the orientation of the gate relative to the crystal structure of the channel. By spreading the forces arising from strain in the films, sensitivity to temperature may be reduced.

In this configuration, as shown in FIG. 11B, the drain (1170) and gate electrodes (1160, 1161) are patterned as curvilinear arcs, rather than linear structures. In an embodiment, rather than inducing an interface strain of identical orientation along the entire gate length, the use of a curvilinear gate decomposes the interface strain into components orthogonal to the underlying channel crystal.

FIG. 11C shows the typical example of environment temperature driven performance degradation of the linear gate configuration of FIG. 11A, in which small-signal current gain (|h21|) in decibels is plotted as a function of frequency, at both 20° C. and 250° C. In FIG. 11C, the small-signal current gain decreases at 250° C. relative to the behavior at 20° C. FIG. 11D shows the same sample performance metric (|h21|) for the curvilinear gate device disclosed in FIG. 11B, which has identical behavior at 20° C., but is degraded less at 250° C.

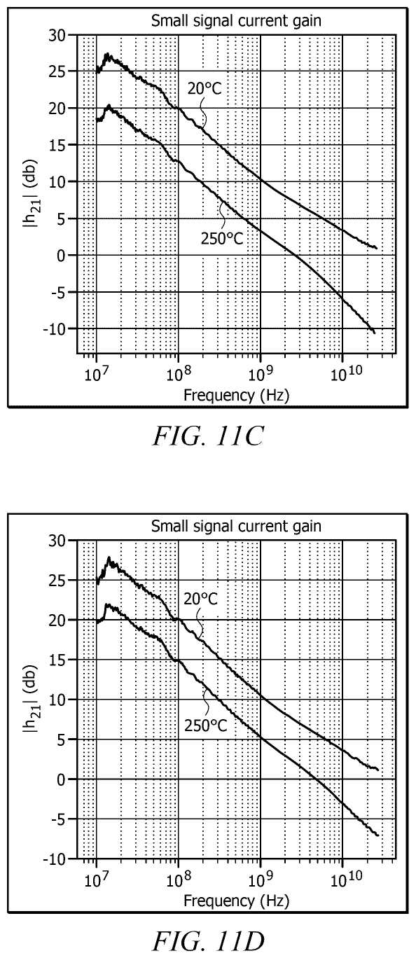

FIGS. 12A-12C illustrate a cross-section view of a device stack configuration including an additional strain layer to stabilize the 2DEG layer at extreme temperatures, according to particular embodiments. In an embodiment, uncompensated strain at a transistor's AlGaN and GaN boundary presents additional degradation of RF functionality in a system having one or more modules (250) when operating at extreme temperatures. Such strain may be mitigated by incorporating methods for stabilizing the piezoelectric field responsible for maintaining the 2DEG channel region of a GaN HEMT device.

A typical GaN device layer stack, as illustrated in FIG. 12A, includes a semiconducting AlGaN layer (1210) and a semiconducting GaN layer (1220). In an embodiment, the current GaN epitaxy utilizes the difference between the lattice structures of the AlGaN layer (1210) and GaN layer (1220) to create an inherent strain (1215) which generates a piezoelectric field to modulate conduction along a HEMT channel region, referred to as a 2DEG layer (1240). Applied bias voltages across the device stack may be used to populate and depopulate the 2DEG region with carriers to operate the transistor.

Because the behavior of the 2DEG layer (1240) degrades with temperature, maximum operating temperatures may be restricted to avoid accompanying change in device behavior. A specialized device stack configuration may be employed to yield higher 2DEG layer stabilization at extreme temperatures.

FIG. 12B discloses a configuration that includes an additional strain layer (1250) beneath the 2DEG layer (1240) which may be contained within (1220). At normal operating temperatures, the presence of the added strain layer (1250) may have no effect or may degrade the overall channel behavior via polarization field (1235) changes. In contrast, at the extreme temperatures encountered during system operation, the presence of this additional lower layer compensates for temperature-dependent changes in inter-layer strain with (1210) and (1220) and, thus, in accompanying field (1230) in a manner such that it stabilizes 2DEG channel layer (1240). As depicted in FIG. 12C, at the extreme temperatures encountered during system operation, the presence of this additional lower layer compensates for temperature-dependent changes in inter-layer strain with (1210) and (1220) and, thus, in accompanying field (1230) in a manner such that it stabilizes 2DEG channel layer (1240).

In an embodiment, thermally induced failure occurring within HEMT devices may be the degradation of Schottky-semiconductor interfaces that may be used as gate electrodes. Current GaN High HEMT devices rely on thin-film metal stacks (e.g., nickel, gold, and platinum) which provide high-work function Schottky gate electrodes. The metal contacts may be adequate for conventional temperature operation; however, at high operating temperatures the strain induced by the mismatch in coefficient of thermal expansion (CTE) between the gate metal and the GaN creates defects that result in increased gate leakage and reduced drain current. These failure modes associated with gate contacts may be a major contributor to the degradation of GaN HEMT performance at elevated temperatures. The minimum gate leakage current of HEMTs is increased due to transport along other defects in the channel layer under the gate. This affects channel mobility and thus the maximum current achievable for a given HEMT. Gate metal may diffuse into the channel causing crystallographic defects creating increased gate leakage and decreasing drain current. There may also be an element of thermionic emission of carriers over the Schottky barrier which increases with temperature. Therefore, the Signal-to-Noise and Gain of both low-noise amplifiers (LNA) and high-power amplifiers (HPA) circuits may be degraded as well.

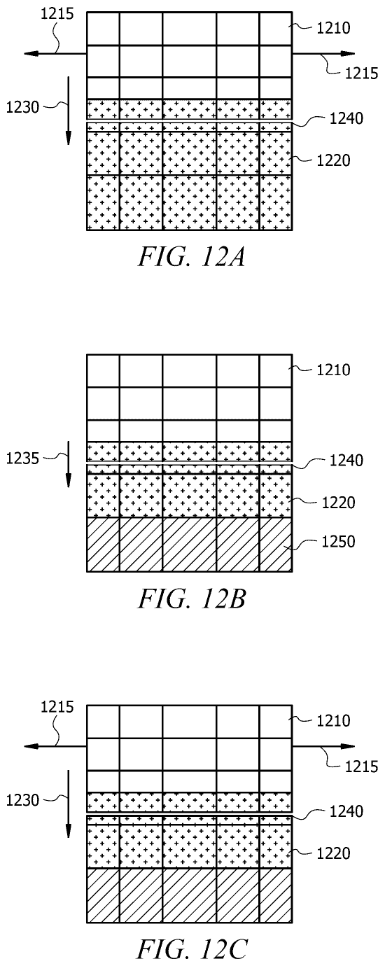

FIG. 13A illustrates a schematic cross-section view of an AlGaN (Aluminum gallium nitride) semiconductor employing conductive metal oxide (e.g., MoO₃, WO₃, V₂O₅) to form the Schottky gate contact of a GaN HEMT accessed via a high work function metal (e.g., Pt, Au, Pd, Ni), according to particular embodiments. By constructing the gate contact using a thin-film stack of a high work function conductive metal oxides (e.g., molybdenum oxide, tungsten oxide, vanadium oxide) and a high work function metal (e.g., palladium or platinum), GaN HEMT performance at high operating temperatures may be improved. The metal oxide buffer layer provides an increased Schottky barrier height and resistivity (since both the work function and resistivity increase with temperature), improved CTE matching which reduces strain and defect formation, reduced diffusion of gate material into the underlying GaN, and better adhesion of the gate to the GaN. In an AlGaN semiconductor (1320) with 2DEG region (1360) accessed by two types of conductive contacts, one contact (1330) forms an ohmic connection suitable for use as a source or drain, while a second contact (1340) forms a Schottky connection suitable for use as a gate. Both contacts may be electrically isolated from other portions of the device by an electrically insulating layer (1310). When (1340) may be associated with a conductive metal oxide, a high work-function metal (1350) may be used to access the gate with other conductive traces within the circuit.

FIG. 13B discloses the use of using an alternative thin-film gate stack wherein a high work function conductive metal oxide layer (1370) (e.g., molybdenum oxide, tungsten oxide, vanadium oxide) and a high work function metal (1380) (e.g., palladium or platinum) are used to improve GaN HEMT performance in extreme temperature operating environments. In the disclosed configuration in FIG. 13B, metal oxide layer (1370) increases both Schottky barrier height and resistivity (since both the work function and resistivity increase with temperature), thus improving CTE matching which reduces strain and defect formation, reducing diffusion of gate material into the underlying GaN, and providing better adhesion of the gate to the GaN.

In some embodiments, multiple techniques may be utilized to construct the conductive metal oxide gate contact of a GaN HEMT. This includes physical vapor deposition (e.g., evaporation, sputtering, atomic-layer deposition) and area-selective atomic layer deposition (ALD) to define the medal oxide region; specifically, a selective etch chemistry for patterning the dielectric without damaging the GaN. Under either construction method, the fabrication process incorporates a novel process of depositing the gate stack at elevated temperatures to “pre-distort” internal film stress, such that the layer “relaxes” when operated at extreme temperatures.

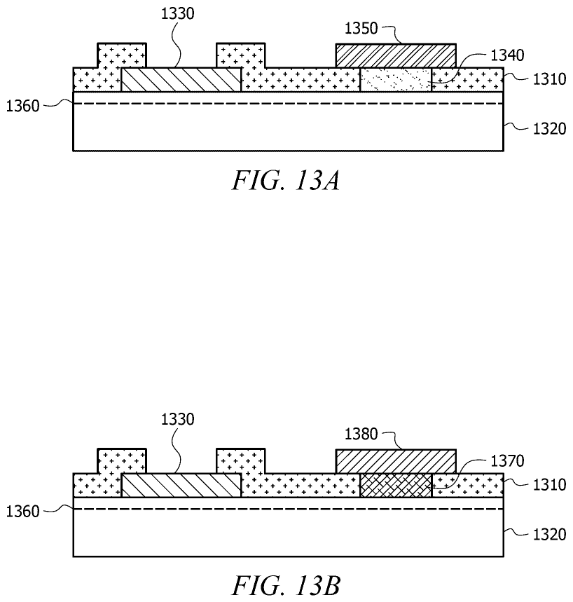

FIG. 14A illustrates a cross-section view of a GaN HEMT structure that includes a substrate (1410) processed with specialized surface treatment methods designed to modify propensity of charges to become trapped at the interface of the semiconductor and subsequently deposited and patterned conductive gate (1450), according to particular embodiments. In an embodiment, a specialized semiconductor surface treatment method may be designed to modify the propensity of charge trapped at the interface of the semiconductor and subsequently deposited and patterned conductive gate. The cross-section of a GaN HEMT structure includes a substrate (1410) on which a GaN (1420) and a AlGaN (1430) layer are deposited. The strain between these two layers creates a 2DEG region (1440) which serves as the channel of the device. Surface states may be often induced by the re-bonding of surface dangling bonds (such as forming surface oxides) and surface contamination (such as the adsorption of gas molecules).

During fabrication, the presence of surface states in the gate and channel region of GaN HEMTs leads to charge trapping and a modification of local polarization fields, negatively impacting the quality of the 2DEG channel layer responsible for HEMT operation. Operation at extreme temperatures amplifies these effects through the greater population of these traps via hot electrons. Thus, the passivation of surface states during fabrication may be a significant element of engineering a GaN HEMT technology for extreme temperature operation. Wet chemical exposure, ultra-violet light, and/or plasma processing techniques may be employed to engineer the bonding landscape of surfaces to discourage the formation of charge trap sites at the interface between thin films. As shown in FIGS. 14B and 14C, replacing terminal hydrogens and oxygens (1460) with nitrogens or sulphurs suppresses the probability of charge trapping after deposition and patterning of gate electrodes. This method effectively creates a non-reactive monolayer barrier between the epitaxial (channel) layer and the gate material that may also suppress charge leakage pathways between gate and channel.

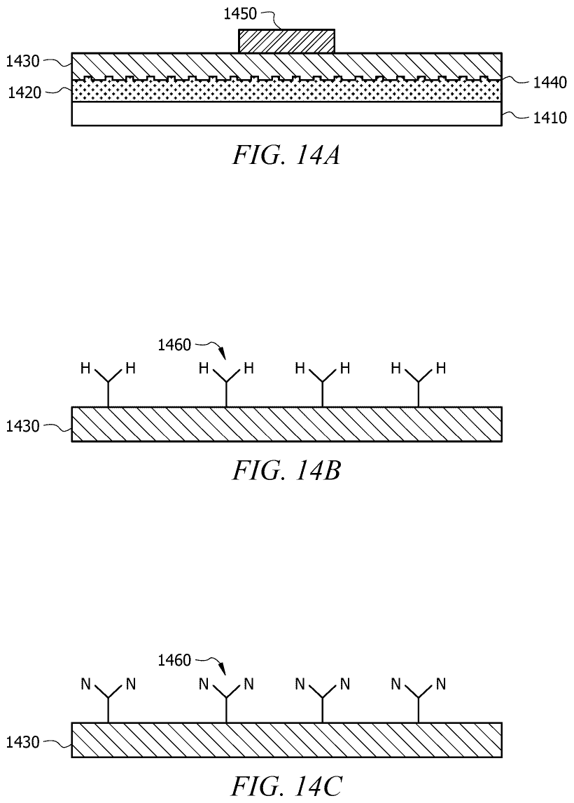

FIG. 15A illustrates a typical passivation layer (1510) such as a film deposited on a substrate (1520) containing microelectronic circuitry. Microelectronic passivation processes are designed to protect circuits from a broad spectrum of environmental contaminates such as high humidity, particle contamination, and mild chemical exposure and are cost, process, and stress optimized to remain robust operating environments up to up to 125° C.

FIGS. 15B and 15C illustrate schematics of a sectioned stress-relaxing passivation (SSRP) feature trench-etched into microelectronic cells, with subsequent use of SSRP features as a tiled combination of geometric cells on a wafer substrate, according to particular embodiments. Some microelectronic passivation processes may be designed to protect circuits from a broad spectrum of environmental contaminates such as high humidity, particle contamination, and mild chemical exposure. Passivation films may include a single dielectric layer that may be cost, process, and stress optimized to remain robust up to 150° C. operating temperatures.

To mitigate thermally induced stresses in passivation thin films and retain robust performance under extreme temperature ranges, a specialized sectioned stress relaxing passivation (SSRP) technique may be required. This technique may use a traditional deposited passivation film or layer (1510) such as silicon dioxide or silicon nitride on the substrate (1520). The passivation layer (1510) may then be trench etched via photo patterning or laser to create stress-relaxing crack regions or cells. The resulting trenches (1530) may be etched down 80% of the original passivation film's (1510) thickness. SSRP may act like any common passivation layer (1510) when in storage, protecting the circuit devices from humidity, particles, and other contaminants. The difference may be, that when the circuit is activated and dealing with extreme temperature, thermally induced film compression of the one or more modules (250) occurs. As a result, the SSRP responds by reorienting to relax film compression stress overload. This may be achieved via a simple redistribution of stress, or by actual cracking in the patterned trenches (1530). The SSRP application may abandon the need for cycle reliability in exchange for targeted extreme temperature stress relief for one cycle.

In an embodiment, the SSRP may be implemented as a tiled combination of geometric cells (e.g., cell designs A, B, & C) on a wafer substrate (1540). Cell design A (1550) uses an 80% etched SSRP grid with a 90º corner to enable the film to fracture at a lower predetermined temperature. Cell design B (1560) incorporates a chamfered corner design, intended to protect a section of the circuit, such as the gate, from stresses at a higher temperature range, thereby offering a graduated inter-grid stress response to increasing thermal loads. Cell design C (1570) uses a three-layer stack design of a layer of SiO₂, a layer of AlSi, followed by another layer of SiO₂. This design may exploit compression relaxing stress voids in the AlSi layer to affect the communication section of GaN device. This response may be matched to a receiving ground device under the same thermal load. The SSRP cell process knobs include trench depth, corner design, patterning process, and passivation material(s).

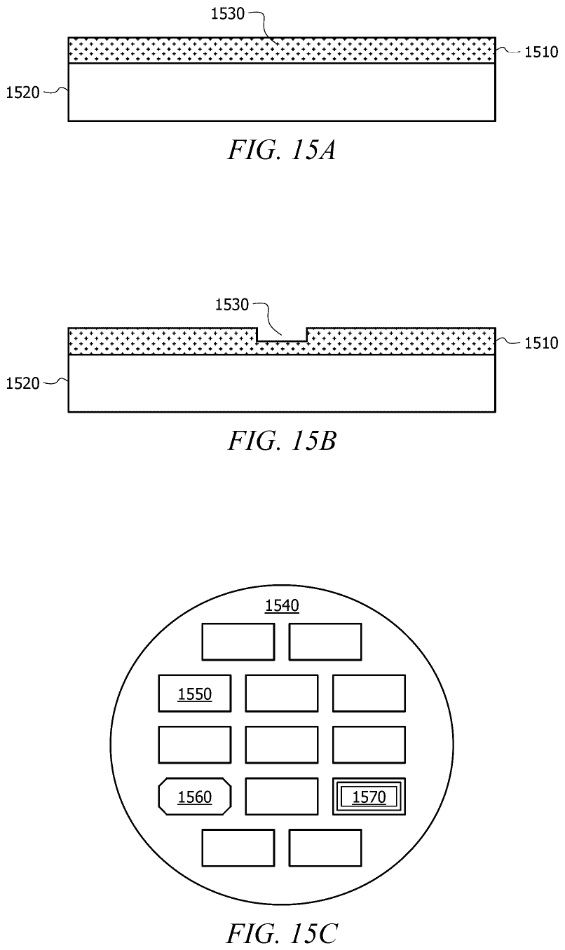

FIG. 16A illustrates a cross-section view of a cell employing specialized material selection and device architectures to enable operation at extreme temperatures, according to particular embodiments. Some conventional HEMT architectures use a non-conductive passivation layer (1610) to provide electrical isolation between the semiconducting transistor 2DEG channel layer (1620), the conductive gate layer (1630), and an interconnect wire layer (1650). Such material interfaces may lead to the unwanted accumulation of charge (1640) at the layer boundaries (e.g., surface states and traps) which may impact device performance and behavior. One such consequence may be the reaction of maximum on-current due to the reduction in available carriers and decreased carrier mobility. As a consequence, the Signal-to-Noise and Gain of both low-noise amplifiers and high-power amplifiers circuits used in one or more modules (250) such as RF modules, may also be degraded.

Typical physical vapor deposition process parameters for creating passivation layers (1610) (e.g., base pressure, deposition rate, substrate temperature, gas concentrations, and ratios) may be chosen to maximize manufacturing uniformity (yield) for devices, assuming maximum operating temperatures under 125° C. At these target operating temperatures, the effect of trapped charge carriers may be much less than other yield variations, so further passivation layer optimization may not be required. For IC dies (310) exposed to extreme operating temperatures, the differential stress which forms between the passivation layer (1610) and the transistor gate later (1630), epitaxial channel layer (1620) and interconnect layers (1650), due to layer composition differences, leads to formation of additional traps. Considering the higher operating temperature, the activation rate of populating these surface states and traps may be exponentially higher and, thus, may contribute significantly to circuit degradation.

In an embodiment, as shown in FIGS. 16B and 16C, specialized approaches may be provided to engineering passivation layers for use at extreme operating temperatures incorporate deposition at high temperature to induce film stress. This creates a “pre-distortion” of the layer during fabrication, such that the layer “relaxes” when operated at high temperatures. Specifically, FIG. 16B illustrates an as-fabricated layer (1660) using growth parameter, to produce preferred level of “pre-distorted” film stress (1670), while FIG. 16C depicts the behavior of a then (1680) after undergoing additional stress response (1690) to an extreme temperature operating environment.

Furthermore, the passivation layer may be deposited in multiple stacked layers, such that internal stresses may be spread across multiple passivation interfaces. This process may include the use of different material compositions per layer. The process flow incorporates further intentional post-fabrication exposure to extreme temperatures as an anneal to affect internal film stress and allow down-selection of best-performing parts. One approach is related to the deposition of a passivation layer with a meta-stable material composition capable of reordering as temperature rises. This approach minimizes temperature-driven interface stresses from differences in CTE between the passivation and channel layer. A second approach may be related to depositing a passivation layer that may be associated with a strain at the elevated operating temperature which counteracts the change in the strain between the AlGaN and GaN layers, such that the 2 Deg layer may be retained.

Beyond the design of circuits and devices, in order to function as part of an engineered system (100), modules (250), in particular embodiments, operating in extreme temperature local environments (110) require their fabrication to be done via specialized process flows. These process flows will produce an IC die (310) containing RF parts of varying physical and electrical characteristics. Given the unique conditions of engineered system (100) and the local environment (110), specialized techniques for a yield-enhancing up-selection process may be employed that enable the identification of individual die comprising MMICs with characteristics suitable for operation in the intended local environment (110).

A key hurdle to overcoming the challenges of operation in extreme temperature local environments (110) is the assumption that the MMIC operates in thermal equilibrium with the environment for successful operation. In this sense, thermal equilibrium means the generation of heat within circuit elements on the IC die (310) must, at a minimum, be balanced by the rejection of heat to an external (cooler) thermal reservoir within the operating environment. This is not, however, necessarily a requirement for successful circuit operation. MMICs may operate in thermal non-equilibrium, albeit with the expectation that self-heating will dictate a monotonic increase in transistor junction temperature and hasten the eventual failure of the part. One consequence of operating in thermal non-equilibrium is that shortened operational lifetimes for MMICs dictate that most development tests become destructive tests. Post-test analysis to determine the characteristics of the best performing parts is more difficult given they no longer operate; therefore, it is valuable to be able to refer back to pre-test sample data and correlate unique characteristics of the best (worst) performing test results. Wafer-level and die-level data acquired during in-line fabrication may be correlated with failure rates of finalized parts. Such data may include both manifest characteristics of fabricated circuits and intermediate DC electrical parameters for as-fabricated layers.

FIG. 17 discloses a test method (1700) based on a non-contact assessment of film morphology, such as visual inspection of grain structure, layer thickness, patterned layer dimensions, and dielectric constants, to identify defects specific to extreme operating temperatures that may occur in a local environment (110).

As one example shown in FIG. 17, fabrication samples (1710) are subjected to visual inspection (1720), to identify the presence of defects so they may be compared (1730) with a pre-compiled database of defects that have been correlated with RF part failure mechanisms (1740). Fabrication samples without defects matching the database continue to fabrication process 1 (1750), while those that match are discarded. This inspect-match-fabricate process (1760) may be repeated an arbitrary number of times, N, with a final matching step (1770) made to make a final accept or discard decision.

This disclosure relates to specialized microelectronics process flows for material selection, device architecture, device fabrication, circuit packaging, circuit integration, thermal pre-treatments, in situ monitoring and control devices, and specialized testing protocols. In an embodiment, the disclosure represents an engineering trade of thermally hardened by-design microelectronics, which applies to operating conditions in which a system containing microelectronic modules performs one or more functions in a high-temperature environment, with the ability to control the thermal environment.

While the disclosure is described with respect to the specific examples, it is to be understood that the scope of the disclosure is not limited to these specific examples, Since other modifications and changes varied to fit particular operating requirements an environments will be apparent to those skilled in the art, the disclosure is not considered limited to the example chosen for purposes of disclosure, and covers all changes and modifications which do not constitute departures from the true spirit and scope of this disclosure.

Although the application described embodiments having specific structural features and/or methodological acts, it is to be understood that the claims are not necessarily limited to the specific features or acts described. Rather, the specific features and acts are merely illustrative of some embodiments that fall within the scope of the claims of the application.

1. A device, comprising:
a substrate;
an integrated circuit die designed to function at a high temperature, wherein the integrated circuit die includes one or more high electron mobility transistors (HEMTs) and wherein the integrated circuit die receives signals from the substrate and transmits signals to the substrate;
a package lid to enclose the integrated circuit die and is disposed on an opposite side of the integrated circuit die from the substrate, wherein the package lid functions as a heatsink;
a thermo-mechanical attachment layer between the integrated circuit die and the package lid; and
one or more microfabricated metal pillars, wherein the one or more microfabricated metal pillars incorporate thermo-mechanical pathways and signal pathways, and wherein the one or more microfabricated metal pillars connect the integrated circuit die to the substrate.

2. The device of claim 1, wherein the integrated circuit die is a monolithic microwave integrated circuit (MMIC) die.

3. The device of claim 1, wherein the integrated circuit die comprises an auxiliary structure for measuring transistor gate temperature, wherein the auxiliary structure comprises a dummy gate within the one or more HEMTs.

4. The device of claim 1, further comprising:
an ablative carbon passivation (ACP) thin film, wherein the ACP thin film ablates in response to elevated temperatures to release thermal energy and redeposits itself on an underside of the package lid.

5. The device of claim 4, wherein the ACP thin film comprises C-60 carbon nanoparticles that are deposited on a surface of the integrated circuit die using thermal evaporation in a vacuum chamber.

6. The device of claim 1, wherein the integrated circuit die includes one or more drains and gate electrodes that are curvilinear arcs.

7. The device of claim 1, wherein the integrated circuit die comprises a GaN HEMT structure that replaces terminal hydrogens and oxygens with any of nitrogens or sulphurs during fabrication.

8. A device, comprising:
a substrate;
an integrated circuit die designed to function at a high temperature, wherein the integrated circuit die includes one or more high electron mobility transistors (HEMTs) and wherein the integrated circuit die receives signals from the substrate and transmits signals to the substrate;
a package lid to enclose the integrated circuit die and is disposed on an opposite side of the integrated circuit die from the substrate, wherein the package lid functions as a heatsink; and
an ablative carbon passivation (ACP) thin film that is disposed between the integrated circuit die and the package lid, wherein the ACP thin film ablates in response to elevated temperatures to release thermal energy and redeposits itself on an underside of the package lid.

9. The device of claim 8, wherein the ACP thin film comprises C-60 carbon nanoparticles that are deposited on a surface of the integrated circuit die using thermal evaporation in a vacuum chamber.

10. The device of claim 8, wherein the integrated circuit die is a monolithic microwave integrated circuit (MMIC) die.

11. The device of claim 8, that further comprises:
One or more microfabricated metal pillars disposed between the substrate and the integrated circuit die, wherein the one or more microfabricated metal pillars incorporate thermo-mechanical pathways and signal pathways, and wherein the one or more microfabricated metal pillars connect the integrated circuit die to the substrate.

12. The device of claim 8, wherein the integrated circuit die includes one or more drains and gate electrodes that are curvilinear arcs.

13. The device of claim 8, wherein a stress-relaxing passivation (SSRP) feature is trench-etched into the substrate.

14. A method for making a device capable of operating in a high temperature environment, the method comprising:
fabricating the device as a plurality of layers on a bulk wafer;
singulating individual usable circuits from the bulk wafer;
testing the individual usable circuits in expected operating conditions after singulating the individual usable circuits; and
combining the individual usable circuits into one or more microelectronic modules for use in a high temperature environment,
wherein the device comprises:
a substrate;
an integrated circuit die designed to function in the high temperature environment and wherein the integrated circuit die receives signals from the substrate and transmits signals to the substrate;
a package lid to enclose the integrated circuit die and is disposed on an opposite side of the integrated circuit die from the substrate;
a thermo-mechanical attachment layer between the integrated circuit die and package lid; and
one or more microfabricated metal pillars.

15. The method of claim 14, wherein the expected operating conditions are temperatures greater than 300 degrees Celsius.

16. The method of claim 14, wherein fabricating further comprises trench etching a stress-relaxing passivation (SSRP) feature into the substrate.

17. The method of claim 14, wherein fabricating further comprises depositing a layer of C-60 carbon nanoparticles onto a surface of the integrated circuit die using thermal evaporation in a vacuum chamber to form an ablative carbon passivation (ACP) thin film.

18. The method of claim 14, wherein device is fabricated by depositing at least a gate stack at an elevated temperature to pre-distort at least one layer of the gate stack.

19. The method of claim 14, wherein during fabrication one or more drains and gate electrodes of the integrated circuit die are curvilinear arcs.

20. The method of claim 14, wherein fabricating further comprises replacing terminal hydrogens and oxygens with any of nitrogens or sulphurs during fabricating of a GaN HEMT structure.
